(19) United States
(12) Patent Application Publication
(10) Pub. No.: US 2022/0238602 A1
(43) Pub. Date: Jul. 28, 2022

(54) SELECTION ELEMENT, MEMORY CELL, AND STORAGE DEVICE

(71) Applicant: SONY SEMICONDUCTOR SOLUTIONS CORPORATION, Kanagawa (JP)

(72) Inventors: Masayuki SHIMUTA, Kanagawa (JP); Tsunenori SHIIMOTO, Kanagawa (JP)

(73) Assignee: SONY SEMICONDUCTOR SOLUTIONS CORPORATION, Kanagawa (JP)

(21) Appl. No.: 17/620,224

(22) PCT Filed: Apr. 22, 2020
(86) PCT No.: PCT/JP2020/017291

§ 371 Date: Dec. 17, 2021

(30) Foreign Application Priority Data
Jun. 26, 2019 (JP) 2019-118281

(51) Int. Cl. H01L 27/24; H01L 27/22

(52) U.S. Cl. CPC H01L 27/2409; H01L 27/224

(57) ABSTRACT

With respect to a selection element that includes a plurality of switch layers and performs selection control in response to an applied voltage, a period in which the selection element can be used is extended. The selection element includes first and second electrodes, a plurality of switch layers, and an intermediate electrode. The first and second electrode are provided to face each other. The intermediate electrode is disposed between the first and second electrodes. The plurality of switch layers are disposed with the intermediate electrode interposed therebetween. A direction in which the plurality of switch layers have the intermediate electrode interposed therebetween is a direction in which the first and second electrodes face each other.

### TECHNICAL FIELD

The present technology relates a selection element. Specifically, the present technology relates to a selection element performing selection control in response to an applied voltage, a memory cell, and a storage device.

### BACKGROUND ART

Recently, nonvolatile memories for data storage represented by a resistor element type memory, such as a resistance random access memory (ReRAM) and phase-change random access memory (PRAM), have been developed. In use of such a nonvolatile memory as a storage device, a configuration of a cross point type memory is receiving attention to reduce a floor area per unit cell to achieve large capacity. In a cross point type memory, memory elements and selection elements are disposed at intersections (cross points) of intersecting wires. Examples of a selection element include a selection element configured using a metal oxide, a selection element in which a resistance value switches at a certain voltage and thus a current abruptly increases (snapback), a selection element using a chalcogenide material (ovonic threshold switch (OTS)), and the like. For example, a selection element using two laminated layers as switch layers has been proposed (refer to PTL 1, for example).

### CITATION LIST

### Patent Literature

[PTL 1]

WO 2016/158429

### SUMMARY

### Technical Problem

In the aforementioned conventional technology, reading or writing of a memory element connected to a selection element can be performed by switching the selection element to an on state. However, when a selection operation is repeated, the selection element deteriorates and thus eventually short-circuits. Even in the case of a selection element having a plurality of switch layers, a formed signal path is common and thus the selection element cannot function when any switch layer deteriorates and causes a short circuit.

The present technology has been devised in such circumstances and an object of the present technology is to extend a period for which a selection element including a plurality of switch layers can be used.

### Solution to Problem

The present technology has been devised to solve the aforementioned problems and a first aspect of the present technology is a selection element, a memory cell, and a storage device including first and second electrodes facing each other, an intermediate electrode disposed between the first and second electrodes, and a plurality of switch layers disposed with the intermediate electrode interposed therebetween in the direction in which the first and second electrodes face each other. Accordingly, even when any of the switch layers has short-circuited due to deterioration, the effect of causing the remaining switch layer to serve as a selection element can be obtained.

Furthermore, in the first aspect, each of the plurality of switch layers may switch to a low resistance state when a voltage higher than a predetermined threshold voltage is applied thereto and may be in a high resistance state in other cases. Accordingly, the effect of performing a switching operation in response to an applied voltage can be obtained.

Furthermore, in the first aspect, at least one of the plurality of switch layers may operate bidirectionally. In addition, at least one of the plurality of switch layers may include a negative resistance component.

Furthermore, in the first aspect, at least one of the plurality of switch layers may contain at least one of oxygen (O), sulfur (S), selenium (Se), and tellurium (Te).

Furthermore, in the first aspect, at least one of the plurality of switch layers may include at least any of a bidirectional diode, an MIM diode, a punch-through diode, a PN diode, a PIN diode, a PIP diode, a Schottky diode, an avalanche diode, and a Zener diode.

Furthermore, in the first aspect, a storage layer disposed between the first and second electrodes may be further included. The storage layer may be any of a resistance change layer formed of a transition metal oxide, a phase change type memory layer, and a magnetic resistance change type memory layer. Furthermore, the storage layer may include an ion source layer and a resistance change layer which are layered. The ion source layer contains a movable element that forms a conductive path in the resistance change layer according to application of electric fields and the movable element may be, for example, a transition metal element, aluminum (Al), copper (Cu), or a chalcogen element. Examples of the chalcogen element include tellurium (Te), selenium (Se), and sulfur (S). Examples of the transition metal element include elements of the fourth group to the sixth group of the periodic table, for example, titanium (Ti), zirconium (Zr), hafnium (Hf), vanadium (V), niobium (Nb), tantalum (Ta), chromium (Cr), molybdenum (Mo), tungsten (W), and the like. The ion source layer contains one kind or two kinds or more of the aforementioned movable elements. In addition, the ion source layer may contain oxygen (O), nitrogen (N), elements other than the aforementioned movable elements (e.g., manganese (Mn), cobalt (Co), iron (Fe), nickel (Ni), and platinum (Pt)), silicon (Si), and the like.

### BRIEF DESCRIPTION OF DRAWINGS

FIG. 1 is a diagram illustrating an example of a three-dimensional image of a cross point type memory in a first embodiment of the present technology.

FIG. 2 is a diagram illustrating an example of a structure of a selection element in an embodiment of the present technology.

FIG. 3 is a diagram illustrating current-voltage characteristics of switch layers.

FIG. 4 is a diagram illustrating film thickness dependency of threshold voltages of switch layers.

FIG. 5 is a diagram illustrating an example of a structure of a memory cell in the first embodiment of the present technology.

FIG. 6 is a diagram illustrating an example of a three-dimensional image of a layered cross point type memory in the first embodiment of the present technology.

FIG. 7 is a diagram illustrating a modified example of a structure of a selection element in an embodiment of the present technology.

FIG. 8 is a diagram illustrating a modified example of a structure of a selection element in the first embodiment of the present technology.

FIG. 9 is a diagram illustrating an example of a three-dimensional image of a cross point type memory in a second embodiment of the present technology.

FIG. 10 is a diagram illustrating an example of a structure of a memory cell in the second embodiment of the present technology.

FIG. 11 is a diagram illustrating an example of a three-dimensional image of a layered cross point type memory in the second embodiment of the present technology.

FIG. 12 is a diagram illustrating a modified example of a structure of a selection element in the second embodiment of the present technology.

### DESCRIPTION OF EMBODIMENTS

Hereinafter, modes for carrying out the present technology (hereinafter referred to as embodiments) will be described. The description will be made in the following order.

1. First embodiment (example in which intermediate electrode is provided between switch layers)

2. Second embodiment (example in which ion source layer is further provided)

### 1. First Embodiment

[Cross Point Type Memory]

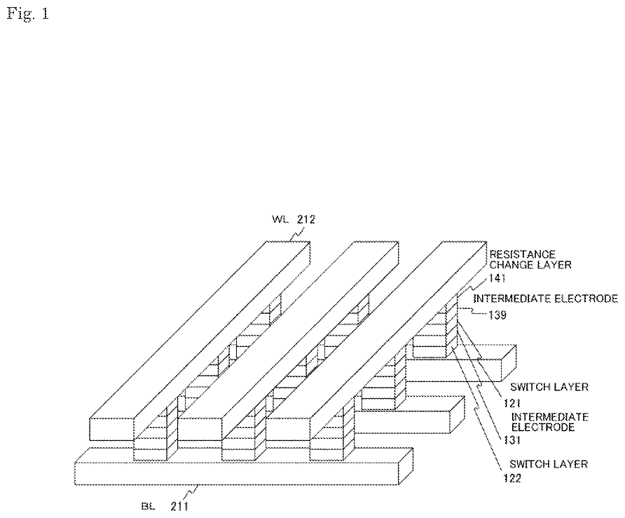

FIG. 1 is a diagram illustrating an example of a three-dimensional image of a cross point type memory in a first embodiment of the present technology.

This cross point type memory is a nonvolatile memory in which memory cells are disposed at intersections of a plurality of bit lines (BL) 211 extending in a predetermined direction and a plurality of word lines (WL) 212 extending in a different direction from the bit lines 211. It is assumed that one side of the plurality of bit lines 211 and the plurality of word lines 212 extends in the vertical direction and the other side extends in the horizontal direction to intersect each other at right angle.

The plurality of bit lines 211 are signal lines through which signals from a bit line decoder are output, and a voltage is applied to memory cells therethrough at a predetermined timing. The plurality of word lines 212 are signal lines through which signals from a word line decoder are output, and a voltage is applied to memory cells therethrough at a predetermined timing. Accordingly, memory cells to which a voltage has been applied are selected and a read or write operation is performed at intersections of the plurality of bit lines 211 and the plurality of word lines 212.

Each of the memory cells at the intersections of the plurality of bit lines 211 and the plurality of word lines 212 includes switch layers 121 and 122, intermediate electrodes 131 and 139, and a resistance change layer 141.

The switch layers 121 and 122 perform a switching operation in response to an applied voltage and have either of an on state and an off state. That is, the switch layers 121 and 122 switch to a low resistance state and turn on when a voltage higher than a predetermined threshold voltage is applied thereto and turn off corresponding to a high resistance state in other cases.

Any of the switch layers 121 and 122 may include, for example, at least one of oxygen (O), sulfur (S), selenium (Se), and tellurium (Te). Any of the switch layers 121 and 122 is assumed to be an ovonic threshold switch (OTS). More specifically, it is desirable to form any of the switch layers 121 and 122 including any composition of BTe, CTe, BCTe, CSiTe, BSiTe, BCSiTe, BTeN, CTeN, BCTeN, CSiTeN, BSiTeN, and BCSiTeN.

The intermediate electrode 131 is an electrode that separates the switch layers 121 and 122 from each other. That is, the switch layers 121 and 122 are disposed with the intermediate electrode 131 interposed therebetween. A direction in which the intermediate electrode 131 is interposed between the switch layers 121 and 122 is a direction in which the bit lines 211 face the word lines 212. In addition, the intermediate electrode 139 is an electrode interposed between the switch layer 121 and the resistance change layer 141.

These intermediate electrodes 131 and 139 may serve to cause the separated switch layers 121 and 122 to turn on or off. Accordingly, the material of the intermediate electrode 131 may be a normal material such as tungsten (W), tungsten nitride (WN), titanium (Ti), titanium nitride (TiN), carbon (C), copper (Cu), aluminum (Al), molybdenum (Mo), tantalum (Ta), tantalum nitride (TaN), ruthenium (Ru), or a silicide thereof.

The resistance change layer 141 is a memory element that has a property that a resistance state thereof changes and represents any one of a low resistance state (LRS) and a high resistance state (HRS). A distribution of cumulative bit numbers when a predetermined read voltage is applied to the resistance change layer 141 is distinguished by any of the low resistance state and the high resistance state on the basis of a predetermined threshold value. In addition, the resistance change layer 141 switches to any of the low resistance state and the high resistance state when a predetermined set voltage or reset voltage is applied thereto. Accordingly, the resistance change layer 141 serves as a memory element representing either of “0” or “1.” Meanwhile, the resistance change layer 141 is an example of a storage layer described in the claims.

The resistance change layer 141 can use a ReRAM, a phase change memory (PCM), a spin transfer torque magnetoresistive random access memory (STT-MRAM), a ferroelectric random access memory (FeRAM), or the like as a resistance change type memory element.

[Characteristics of Selection Element]

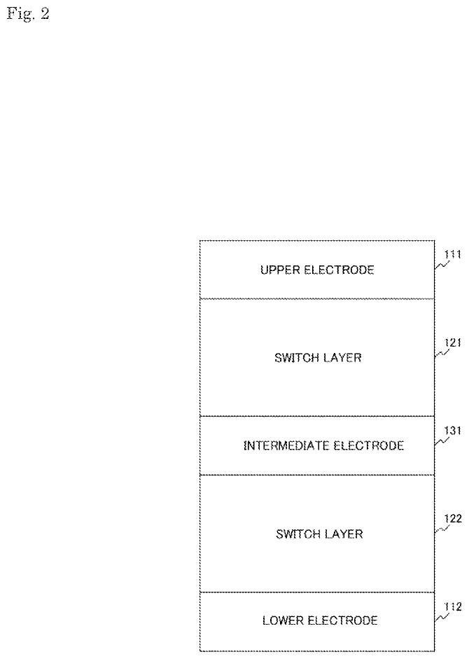

FIG. 2 is a diagram illustrating an example of a structure of a selection element in an embodiment of the present technology.

As described above, the switch layers 121 and 122 are separated by the intermediate electrode 131 and are disposed with the intermediate electrode 131 interposed therebetween. Here, a structure of a selection element is represented. In this example, an upper electrode 111 is illustrated above the switch layer 121 and a lower electrode 112 is illustrated below the switch layer 122. Meanwhile, the upper electrode 111 and the lower electrode 112 are examples of first and second electrodes described in the claims

Hereinafter, characteristics of the selection element with respect to this structure will be considered.

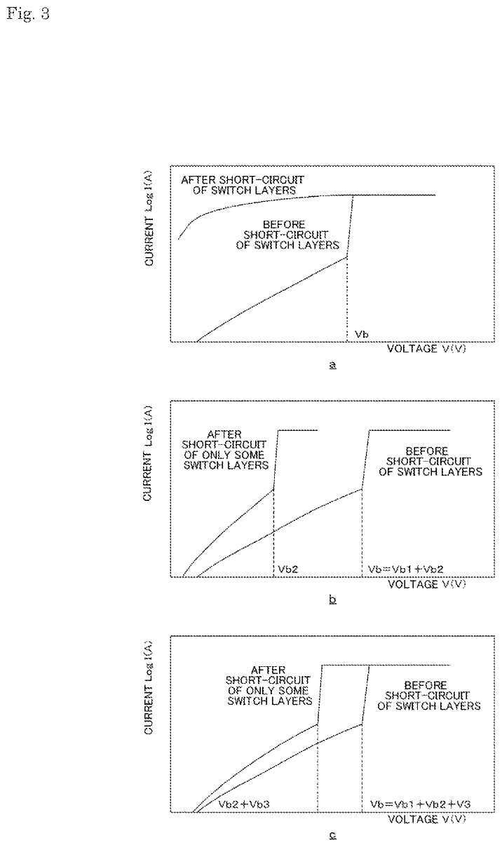

FIG. 3 is a diagram illustrating current-voltage characteristics of switch layers. FIG. 3 shows characteristics of current limitations according to serial connection of a selection element and a transistor.

In FIG. 3, a shows current-voltage characteristics before and after a switch layer in a conventional structure deteriorates and short-circuits according to repeated operations. It is assumed that a threshold voltage of the switch layer before deterioration is Vb. The switch layer can switch current in response to a voltage on the basis of the threshold voltage Vb and thus has a function as a switch layer before deterioration. However, it can be ascertained that the switch layer short-circuits and thus does not have the function as a switch layer for voltage variation after deterioration. Accordingly, when the switch layer deteriorates and short-circuits according to repeated operations, a large current flows through a memory element combined with the short-circuited selection element, other memory elements on the same wire cannot be selected, and thus information of such memory elements is lost.

In FIG. 3, b shows current-voltage characteristics before and after one of the switch layers 121 and 122 separated by the intermediate electrode 131 deteriorates and short-circuits in an embodiment of the present technology. At this time, when threshold voltages of the switch layers 121 and 122 are assumed to be Vb1 and Vb2, a threshold voltage Vb of a selection element composed of a combination of the switch layers 121 and 122 is Vb=Vb1+Vb2 before deterioration and short-circuiting and becomes Vb2 after short-circuiting. That is, in this case, even if only one switch layer short-circuits, the switch layers 121 and 122 serve as a selection element having the threshold voltage of Vb2 according to the other switch layer. If a voltage applied to this selection element is the threshold voltage Vb2 or less, other memory elements on the same wire can also be selected. It is possible to avoid loss of information because information of other memory elements on the same wire can be read and transferred to memory elements on a different wire at a time at which any one of the switch layers 121 and 122 short-circuits.

In addition, when any one of the switch layers 121 and 122 has short-circuited according to repeated operations, it serves as a selection element having a threshold voltage of Vb1 or Vb2. When the levels of Vb1 and Vb2 are different, it is difficult to determine which one of the switch layers 121 and 122 has deteriorated and short-circuited first for each selection element, and thus it is necessary to handle the switch layers 121 and 122 as a selection element having a lower threshold voltage between Vb1 and Vb2. Further, a selection element having a higher threshold voltage is generally desirable as a selection element of a cross point type memory. Accordingly, the threshold voltage of the selection element when any one of the switch layers 121 and 122 has deteriorated and short-circuited is maximized in a case where Vb1 and Vb2 have the same level. At this time, the threshold voltage for serving as a selection element does not change irrespective of which one short-circuits first, and a threshold voltage when any one of the switch layers 121 and 122 has deteriorated and short-circuited first becomes half of that before any one deteriorated and short-circuited. Accordingly, when one of the switch layers 121 and 122 has deteriorated and short-circuited, it is desirable that Vb1 and Vb2 have the same level in order to cause the switch layers 121 and 122 to serve as a selection element having a higher threshold voltage. Therefore, it is desirable that the switch layers 121 and 122 be formed of the same kind of material such that Vb1 and Vb2 have the same level.

In FIG. 3, c shows current-voltage characteristics in a case where three switch layers are electrically connected to serve as a single selection element. When threshold voltages of the three switch layers are Vb1, Vb2, and Vb3, a threshold voltage of a single selection element is Vb=Vb1+Vb2+Vb3. Even if a switch layer having the threshold value of Vb1, for example, among the three switch layers deteriorates and short-circuits according to repeated operations, the switch layers can serve as a selection element having a threshold voltage Vb=Vb2+Vb3. For example, in a case where Vb1, Vb2, and Vb3 have the same level, when any one of the switch layers deteriorates and short-circuits, the threshold voltage of the selection element is two thirds of that before deterioration. As compared to a case in which there are two switch layers, the threshold voltage serving as the selection element can be increased. In this manner, the number of switch layers constituting a single selection element is not limited to two and may be three or more.

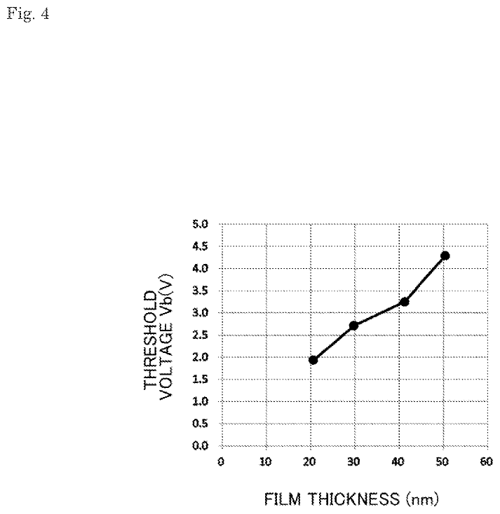

FIG. 4 is a diagram illustrating film thickness dependency of threshold voltages of switch layers.

In FIG. 4, BCTeN containing tellurium (Te) that is a chalcogenide element is assumed as a switch layer. In addition, one electrode is assumed to be titanium (TiN) and other electrode is assumed to be tungsten (W). Meanwhile, FIG. 4 shows values when an intermediate electrode is not included.

It can be ascertained from this figure that a film thickness of 45 nm or more is necessary to obtain a threshold voltage of 4 V, for example, for a switch layer that does not include an intermediate electrode as in the conventional technology. On the other hand, when the switch layers 121 and 122 are used as in this embodiment, the switch layers 121 and 122 have threshold voltages of 2 V when they have a film thickness of 20 nm. That is, a film thickness of a total of 40 nm is sufficient to obtain a threshold voltage of a total of 4 V according to the switch layers 121 and 122. This is because, when the resistance component of the intermediate electrode 131 is assumed to be about several kΩ, the threshold voltage is not affected by the intermediate electrode 131 and thus the serially connected switch layers 121 and 122 are considered to serve as a single selection element having a threshold voltage of 4 V.

Accordingly, the switch layers 121 and 122 are separated by the intermediate electrode 131 and thus the film thickness can be reduced. Since the intermediate electrode 131 is assumed to have a thickness of about 1 to 2 nm, the influence of the thickness of the intermediate electrode 131 itself is insignificant. Even if the switch layers 121 and 122 are separated by the intermediate electrode 131 in this manner, the electrically serially connected switch layers serve as a single selection element and thus can have the same threshold voltage as that in the conventional technology. At this time, the total film thickness of the switch layers 121 and 122 can be reduced, and thus an aspect ratio during etching processing is decreased, which is advantageous for miniaturization. In addition, when the switch layers 121 and 122 are formed of different materials, conditions for etching processing change and productivity of fine processing may deteriorate, and thus it is desirable to form the switch layers 121 and 122 of the same kind of material.

In this manner, the effects of the selection element for a cross point type memory are obtained by serially connecting the plurality of switch layers 121 and 122 separated by the intermediate electrode 131 in principle. Accordingly, when the selection element is combined with a memory element that operates bidirectionally, such as a ReRAM, any of the switch layers 121 and 122 may be a bidirectional diode, that is, a switch layer that operates bidirectionally, such as a metal-insulator-metal (MIM) diodes and a punch-through diode, irrespective of the type thereof.

In addition, any of the switch layers 121 and 122 may have a negative resistance component as a voltage-current characteristic. At this time, the switch layers 121 and 122 switch to an on state and thus a divided voltage related to the switch layers 121 and 122 is reduced, and a divided voltage applied to a serially connected memory element increases by the same level. As compared to a case in which neither of the switch layers 121 and 122 has a negative resistance component, a net voltage necessary to drive the serially connected selection element and memory element can be reduced because the divided voltage applied to the memory element increases. Accordingly, a switch layer that has a negative resistance component such as a material containing a chalcogenide element, that is, a so-called OTS material, and can operate bidirectionally is desirable.

In addition, in a selection element combined with a resistance change memory that operates unidirectionally, such as a PCM, a plurality of switch layers 121 and 122 constituting the selection element may operate unidirectionally. As described above, if the plurality of switch layers are serially connected, any of the switch layers 121 and 122 may be a PN diode, a P-intrinsic-N (PIN) diode, a P-intrinsic-P (PIP) diode, a Schottky diode, a Zener diode, and an avalanche diode irrespective of the type thereof.

In addition, when the switch layers 121 and 122 have a negative resistance component, the following advantages are obtained. In general, at the time of state transition between an off state and an on state, a phenomenon that differential resistance of current-voltage characteristics becomes negative (negative differential resistance) often appears when a chalcogen element is included. When a switch layer switches to an on state, a divided voltage of the switch layer is reduced. A wire connected to both ends of the selection element and the memory element has parasitic capacitance, and a phenomenon that the amount of charges accumulated in the parasitic capacitance associated with such voltage variation changes and thus transient current flows occurs. According to this transient current, the performance of the selection element and the memory element deteriorates. For example, in the case of a memory operating using heat as the operation principle, such as a PCM, a resistance value of a memory element changes according to Joule heat due to transient current and thus a malfunction of the memory can occur. With respect to this, in this embodiment, curbing of transient current according to a resistance component of the intermediate electrode 131 can be expected by including the intermediate electrode 131. That is, if the switch layers 121 and 122 are in an on state, they have a resistance on an order of several kΩ to tens of kΩ but the resistance component of the intermediate electrode 131 is also several kΩ to tens of kΩ, and thus transient current can be curbed. Meanwhile, when the switch layers 121 and 122 are in an off state, they have a high resistance of several MΩ or more, and thus the resistance component of the intermediate electrode 131 is sufficiently low and the intermediate electrode 131 does not affect the aforementioned threshold voltage.

Further, the switch layers 121 and 122 may be a selection element in which a resistance value switches at a certain voltage and current abruptly increases (snapback) or a nonlinear resistant layer that does not snap back.

[Disposition of Resistance Change Layer]

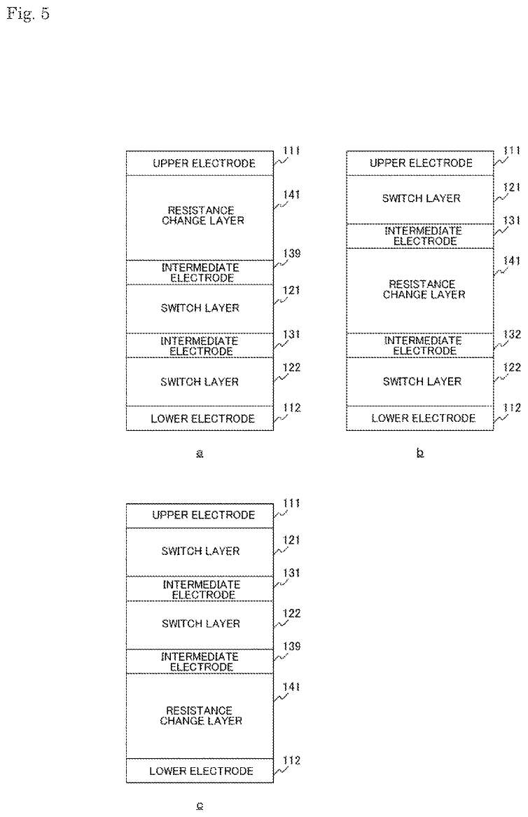

FIG. 5 is a diagram illustrating an example of a structure of a memory cell in a first embodiment of the present technology.

In FIG. 5, a shows an example of the same structure as the above-described cross point type memory. In this example, the resistance change layer 141 is disposed directly below the upper electrode 111. However, this resistance change layer 141 may be disposed at any position between the upper electrode 111 and the lower electrode 112.

Accordingly, as shown in b of FIG. 5, the resistance change layer 141 may be disposed between the switch layers 121 and 122. In addition, as shown in c of FIG. 5, the resistance change layer 141 may be disposed directly on the lower electrode 112.

[Layered Cross Point Type Memory]

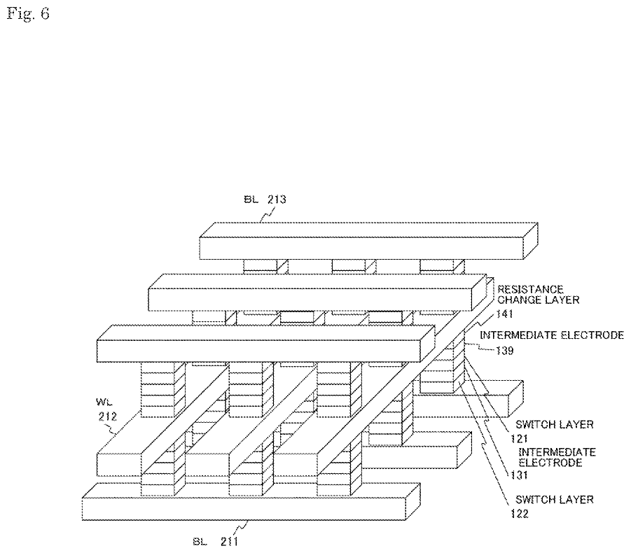

FIG. 6 is a diagram illustrating an example of a three-dimensional image of a layered cross point type memory in the first embodiment of the present technology.

In the above-described example, an example of a cross point type memory in which the bit lines 211 and word lines 212 in pairs are provided and memory cells are provided at intersections thereof has been described. Here, an example of a layered cross point type memory in which bit lines 213 are further provided and memory cells are further provided at intersections of the bit lines 213 and the word lines 212 is represented.

In this layered cross point type memory, the switch layer 121 and the switch layer 122 are separated by the intermediate electrode 131 in each memory cell as in the above-described single-layer cross point type memory. Accordingly, the same effects as those of the above-described single-layer cross point type memory can be obtained.

### MODIFIED EXAMPLES

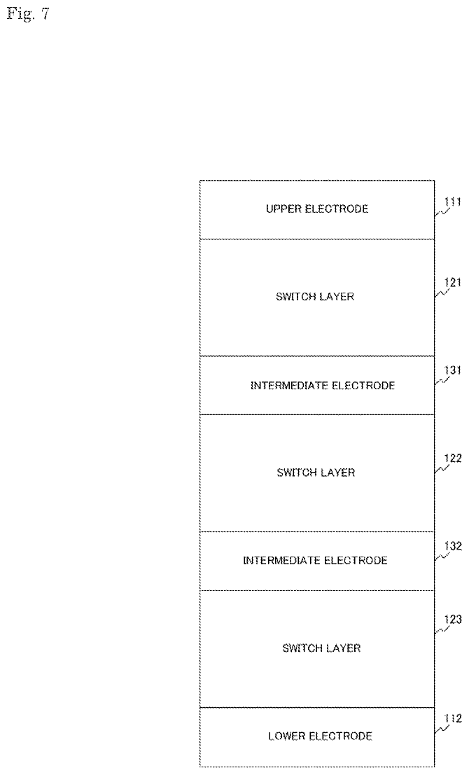

FIG. 7 is a diagram showing a modified example of a structure of a selection element in an embodiment of the present technology.

In the above-described example, an example of separating the two switch layers 121 and 122 according to the intermediate electrode 131 has been described. Here, an example in which an intermediate electrode 132 is further provided to separate the three switch layers 121 to 123 is represented. That is, since the effects in this embodiment are obtained from serial connection of a plurality of switch layers, the number of switch layers is not limited to two and may be three or more as represented in this example.

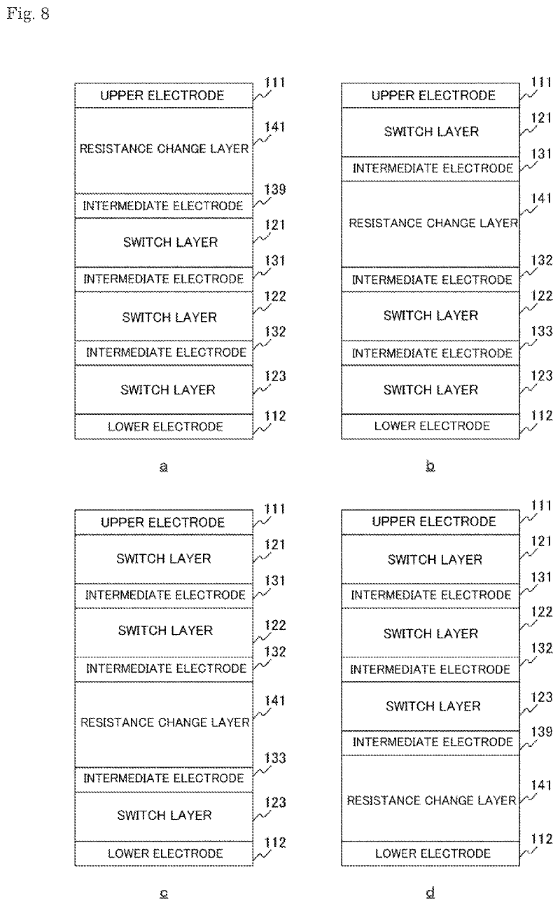

FIG. 8 is a diagram illustrating a modified example of a structure of a selection element in the first embodiment of the present technology.

Here, an example of a case in which three switch layers 121 to 123 are separated as described above is represented. In this case, the resistance change layer 141 may also be disposed at any position between the upper electrode 111 and the lower electrode 112.

In a of FIG. 8, the resistance change layer 141 is disposed directly below the upper electrode 111. In b of FIG. 8, the resistance change layer 141 is disposed between the switch layers 121 and 122. In c of FIG. 8, the resistance change layer 141 is disposed between the switch layers 122 and 123. In addition, in d of FIG. 8, the resistance change layer 141 is disposed directly above the lower electrode 112.

Meanwhile, in this modified example, some intermediate electrodes may be omitted as necessary. Accordingly, a process of changing an etching chamber at the time of etching can be omitted and thus a manufacturing process can be simplified.

In this manner, according to the first embodiment of the present technology, a plurality of switch layers are separated by the intermediate electrode, and thus, even when any switch layer has short-circuited due to deterioration, the remaining switch layer can serve as a selection element. Accordingly, it is possible to reduce the film thickness of the switch layers. Furthermore, when the switch layers have a negative resistance component, transient current due to Joule heat generated at the time of transition to an on state can be curbed.

### 2. Second Embodiment

[Cross Point Type Memory]

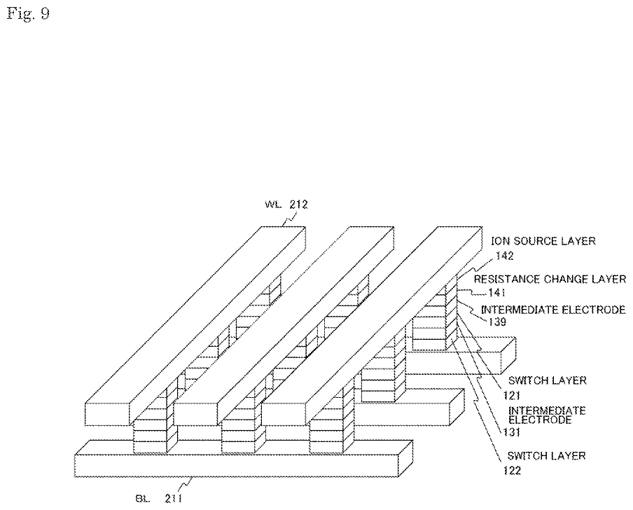

FIG. 9 is a diagram illustrating an example of a three-dimensional image of a cross point type memory in a second embodiment of the present technology.

A cross point type memory in the second embodiment is identical to that in the above-described first embodiment in that the memory cells are disposed at intersections of the plurality of bit lines 211 and the plurality of word lines 212. Although the memory element is composed of the resistance change layer 141 in the first embodiment, a memory element of the second embodiment is composed of a layered structure of the resistance change layer 141 and an ion source layer 142.

The ion source layer 142 contains a movable element that forms a conductive path in the resistance change layer 141 according to application of electric fields. This movable element may be, for example, a transition metal element, aluminum (Al), copper (Cu), or a chalcogen element. Examples of the chalcogen element include tellurium (Te), selenium (Se), and sulfur (S). Examples of the transition metal element include elements of the fourth group to the sixth group of the periodic table, for example, titanium (Ti), zirconium (Zr), hafnium (Hf), vanadium (V), niobium (Nb), tantalum (Ta), chromium (Cr), molybdenum (Mo), tungsten (W), and the like. The ion source layer 142 contains one kind or two kinds or more of the aforementioned movable elements. In addition, the ion source layer 142 may contain oxygen (O), nitrogen (N), elements other than the aforementioned movable elements (e.g., manganese (Mn), cobalt (Co), iron (Fe), nickel (Ni), and platinum (Pt)), silicon (Si), and the like. Meanwhile, the ion source layer 142 is an example of a storage layer described in the claims.

[Disposition of Resistance Change Layer]

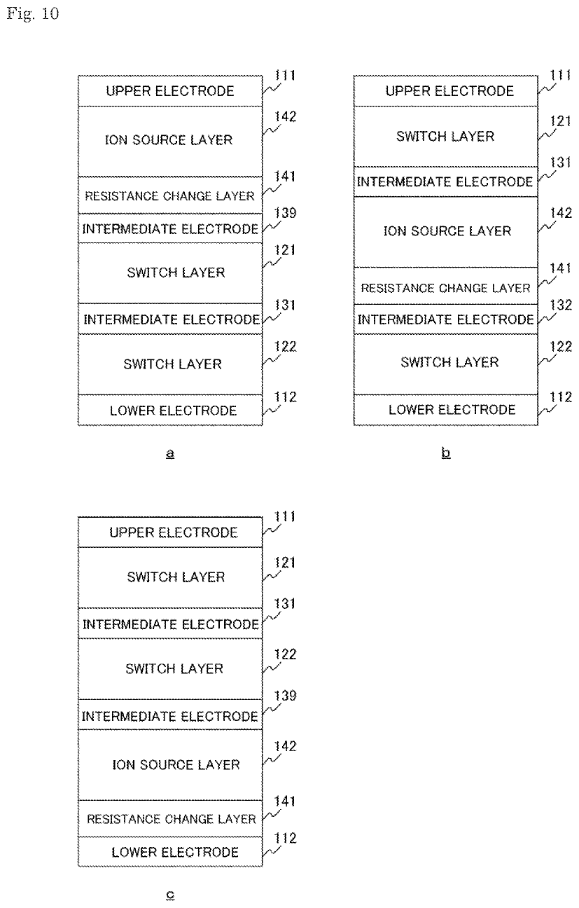

FIG. 10 is a diagram illustrating an example of a structure of a memory cell in the second embodiment of the present technology.

In FIG. 10, a shows an example of the same structure as the aforementioned cross point type memory in the second embodiment. In this example, the resistance change layer 141 and the ion source layer 142 are disposed directly below the upper electrode 111. However, the resistance change layer 141 and the ion source layer 142 may be disposed at any position between the upper electrode 111 and the lower electrode 112.

Accordingly, as shown in b of FIG. 10, the resistance change layer 141 may be disposed between the switch layers 121 and 122. In addition, as shown in c of FIG. 10, the resistance change layer 141 may be disposed directly on the lower electrode 112.

[Layered Cross Point Type Memory]

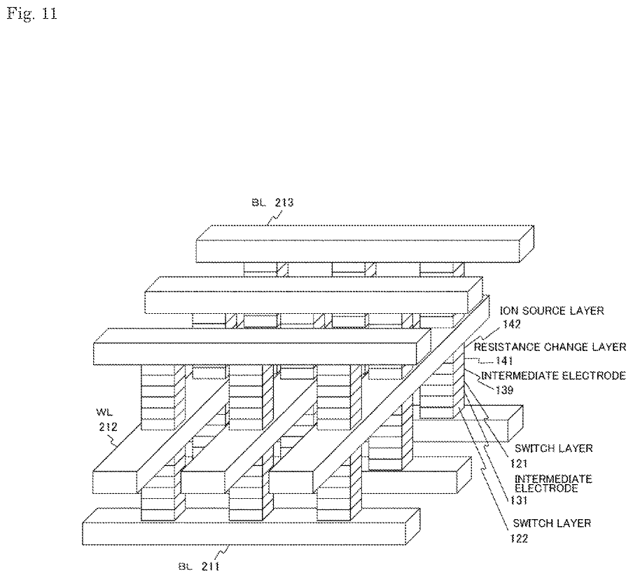

FIG. 11 is a diagram illustrating an example of a three-dimensional image of a layered cross point type memory in the second embodiment of the present technology.

In the above-described example, an example of a cross point type memory in which the bit lines 211 and word lines 212 in pairs are provided and memory cells are provided at intersections thereof has been described. Here, an example of a layered cross point type memory in which the bit lines 213 are further provided and memory cells are further provided at the intersections of the bit lines 213 and the word lines 212 as in the case of the above-described first embodiment is represented.

In this layered cross point type memory, the switch layer 121 and the switch layer 122 are separated by the intermediate electrode 131 in each memory cell as in the above-described single-layer cross point type memory. Accordingly, the same effects as those of the above-described single-layer cross point type memory can be obtained.

### MODIFIED EXAMPLES

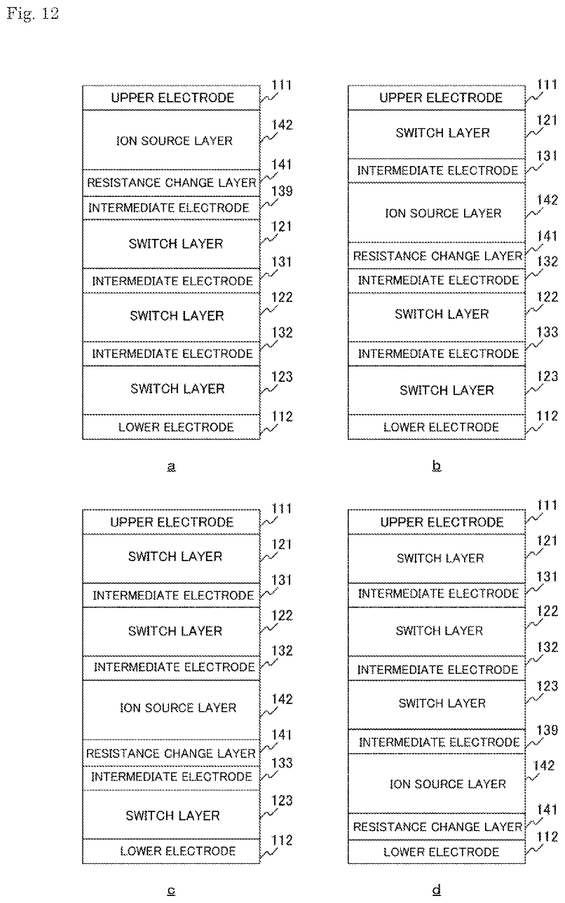

FIG. 12 is a diagram illustrating a modified example of a structure of a selection element in the second embodiment of the present technology.

As described above in the first embodiment, the number of switch layers is not limited to two and may be three or more. Here, an example of a case in which three switch layers 121 to 123 are separated as described above is represented. In this case, the resistance change layer 141 and the ion source layer 142 may also be disposed at any position between the upper electrode 111 and the lower electrode 112.

In a of FIG. 12, the resistance change layer 141 and the ion source layer 142 may be disposed directly below the upper electrode 111. In b of FIG. 12, the resistance change layer 141 and the ion source layer 142 may be disposed between the switch layers 121 and 122. Inc of FIG. 12, the resistance change layer 141 and the ion source layer 142 may be disposed between the switch layers 122 and 123. In addition, in d of FIG. 12, the resistance change layer 141 and the ion source layer 142 may be disposed directly on the lower electrode 112.

In this manner, according to the second embodiment of the present disclosure, the above-described effects according to separation of the plurality of switch layers by the intermediate electrode can be obtained even in a case in which the resistance change layer 141 and the ion source layer 142 are used as a memory element.

The above-described embodiment is a mode for carrying out the present technology and the factors in the embodiment have the respective correspondence relation with the specific factors of the invention in the claims. Similarly, the specific factors of the invention in the claims have the respective correspondence relation with the factors with the same names in the embodiment of the present technology. Here, the present technology is not limited to the embodiment and various modifications of the embodiment can be made within the scope of the present technology without departing from the gist of the present technology.

The present technology can be configured as follows.

(1) A selection element including first and second electrodes facing each other, an intermediate electrode disposed between the first and second electrodes, and a plurality of switch layers disposed with the intermediate electrode interposed therebetween in the direction in which the first and second electrodes face each other.

(2) The selection element according to (1), wherein each of the plurality of switch layers switches to a low resistance state when a voltage higher than a predetermined threshold voltage is applied thereto and is in a high resistance state in other cases.

(3) The selection element according to (1) or (2), wherein at least one of the plurality of switch layers can operate bidirectionally.

(4) The selection element according to any of (1) to (3), wherein at least one of the plurality of switch layers includes a negative resistance component.

(5) The selection element according to any of (1) to (4), wherein at least one of the plurality of switch layers contains at least one of oxygen (O), sulfur (S), selenium (Se), and tellurium (Te).

(6) The selection element according to any of (1) to (5), wherein at least one of the plurality of switch layers includes a bidirectional diode.

(7) The selection element according to any of (1) to (5), wherein at least one of the plurality of switch layers includes at least any of an MIM diode and a punch-through diode.

(8) The selection element according to any of (1) to (5), wherein at least one of the plurality of switch layers includes at least any of a PN diode, a PIN diode, a PIP diode, a Schottky diode, an avalanche diode, and a Zener diode.

(9) The selection element according to (1), wherein all the plurality of switch layers are formed of the same kind of material.

(10) A memory cell including first and second electrodes facing each other, a storage layer disposed between the first and second electrodes,

an intermediate electrode disposed between the first and second electrodes, and a plurality of switch layers disposed with the intermediate electrode interposed therebetween in the direction in which the first and second electrodes face each other.

(11) The memory cell according to (9), wherein the storage layer is any of a resistance change layer formed of a transition metal oxide, a phase change type memory layer, and a magnetic resistance change type memory layer.

(12) The memory cell according to (9), wherein the storage layer includes an ion source layer containing at least one of tellurium (Te), aluminum (Al), copper (Cu), zirconium (Zr), nitrogen (N), and oxygen (O) and a resistance change layer formed of an oxide material.

(13) The memory cell according to any of (9) to (11), wherein at least one of the plurality of switch layers contains at least one of oxygen (O), sulfur (S), selenium (Se), and tellurium (Te).

(14) A storage device including a plurality of memory cells each including first and second electrodes facing each other, a storage layer disposed between the first and second electrodes, an intermediate electrode disposed between the first and second electrodes, and a plurality of switch layers disposed with the intermediate electrode interposed therebetween in the direction in which the first and second electrodes face each other.

### REFERENCE SIGNS LIST

111 Upper electrode

112 Lower electrode

121, 122, 123 Switch layer

131, 132, 133, 139 Intermediate electrode

141 Resistance change layer

142 Ion source layer

211, 213 Bit line

212 Word line

What is claimed is:

1. A selection element comprising:
a first electrode and a second electrode facing each other;
an intermediate electrode disposed between the first and second electrodes; and
a plurality of switch layers disposed with the intermediate electrode interposed therebetween in the direction in which the first and second electrodes face each other.

2. The selection element according to claim 1, wherein each of the plurality of switch layers switches to a low resistance state when a voltage higher than a predetermined threshold voltage is applied thereto and is in a high resistance state in other cases.

3. The selection element according to claim 1, wherein at least one of the plurality of switch layers is able to operate bidirectionally.

4. The selection element according to claim 1, wherein at least one of the plurality of switch layers includes a negative resistance component.

5. The selection element according to claim 1, wherein at least one of the plurality of switch layers contains at least one of oxygen (O), sulfur (S), selenium (Se), and tellurium (Te).

6. The selection element according to claim 1, wherein at least one of the plurality of switch layers includes a bidirectional diode.

7. The selection element according to claim 1, wherein at least one of the plurality of switch layers includes at least any of an MIM diode and a punch-through diode.

8. The selection element according to claim 1, wherein at least one of the plurality of switch layers includes at least any of a PN diode, a PIN diode, a PIP diode, a Schottky diode, an avalanche diode, and a Zener diode.

9. The selection element according to claim 1, wherein all the plurality of switch layers are formed of the same kind of material.

10. A memory cell, comprising:
a first electrode and a second electrode facing each other;
a storage layer disposed between the first and second electrodes;
an intermediate electrode disposed between the first and second electrodes; and
a plurality of switch layers disposed with the intermediate electrode interposed therebetween in the direction in which the first and second electrodes face each other.

11. The memory cell according to claim 9, wherein the storage layer is any of a resistance change layer formed of a transition metal oxide, a phase change type memory layer, and a magnetic resistance change type memory layer.

12. The memory cell according to claim 9, wherein the storage layer includes an ion source layer containing at least one of tellurium (Te), aluminum (Al), copper (Cu), zirconium (Zr), nitrogen (N), and oxygen (O) and a resistance change layer formed of an oxide material.

13. The memory cell according to claim 9, wherein at least one of the plurality of switch layers contains at least one of oxygen (O), sulfur (S), selenium (Se), and tellurium (Te).

14. A storage device comprising a plurality of memory cells, each comprising:
first and second electrodes facing each other,
a storage layer disposed between the first and second electrodes,
an intermediate electrode disposed between the first and second electrodes,
and a plurality of switch layers disposed with the intermediate electrode interposed therebetween in the direction in which the first and second electrodes face each other.
